(19) United States
(12) Patent Application Publication
(10) Pub. No.: US 2025/0157824 A1
(43) Pub. Date: May 15, 2025

(54) Selective metal Capping with Metal Halide enhancement

(71) Applicant: Applied Materials, Inc., Santa Clara, CA (US)

(72) Inventors: Shumao ZHANG, San Jose, CA (US); Qihao ZHU, Sunnyvale, CA (US); Liqi WU, San Jose, CA (US); Chih-Hsun HSU, Santa Clara, CA (US); Jiang LU, Milpitas, CA (US); Rongjun WANG, Dublin, CA (US)

(21) Appl. No.: 18/947,949

(22) Filed: Nov. 14, 2024

Related U.S. Application Data
(60) Provisional application No. 63/599,427, filed on Nov. 15, 2023.

(51) Int. Cl. H01L 21/285; C23C 16/455; C23C 16/458; C23C 16/52; H01L 21/02

(52) U.S. Cl. CPC H01L 21/28562; C23C 16/45553; C23C 16/4584; C23C 16/52; H01L 21/02068; H01L 21/02697

(57) ABSTRACT

Embodiments of the present disclosure generally relate to methods and processes for selectively depositing a metal fill layer into a feature on the surface of a semiconductor structure. In some embodiments, a method of forming a contact structure includes performing a preclean operation on a contact structure to form a precleaned contact structure. The contact structure includes a silicon-based portion exposed in a cavity of a substrate. The method further includes depositing a metal layer over the precleaned contact structure to form a deposited contact structure. The method further includes introducing a metal halide precursor to the deposited contact structure to at least partially remove the second layer from the deposited contact structure to form an etched contact structure. The method further includes depositing a metal fill layer onto the first layer to form a filled contact structure. The deposited metal fill layer comprises a super conformal profile.

### BACKGROUND

### Related Application

This application claims the benefit of priority to U.S. Patent Application No. 63/599,427 filed Nov. 15, 2023, the entire disclosure of which is incorporated by reference herein.

### Field

Embodiments of the present disclosure generally relate to methods and processes for selectively depositing a metal fill layer into a feature on the surface of a semiconductor structure. More specifically, embodiments described herein provide for methods of super-conformally depositing a metal fill layer into a feature on the surface of a semiconductor structure in a bottom-up manner.

### Description of the Related Art

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

In a traditional middle-end-of-the-line (MEOL) contact junction formation process, a feature, such as a via or trench, is fabricated in the semiconductor substrate. A silicon (Si) or silicon/germanium (SiGe)-comprising contact region is formed in the trench or via bottom. MEOL contact junctions allow connections between front-end-of-the-line (FEOL) semiconductor structures and back-end-of-the-line (BEOL) interconnects. Contacts with a low resistivity are desirable in semiconductor devices. However, when a MEOL contact junction has a relatively high resistance, a poor connection is created at the MEOL contact junction, which reduces the overall performance of the packaged semiconductor structures.

Following a conventional silicide formation process, the feature is filled with a low resistivity metal, either by cobalt (Co) or tungsten (W). For a tungsten (W) contact, the structure is filled by a traditional W conformal deposition process. Conventional fill processes form a seam during the filling process, which can cause a significant (greater than 50%) line resistance increase as compared to a completely filled feature. However, conventional silicide layer formation processes require the formation of a deposited metal containing layer to be formed on the bottom, sidewalls and field regions of the substrate that leads to the formation of a seam in the feature when a conventional conformal chemical vapor deposition (CVD) or atomic layer deposition (ALD) process is used to fill the feature.

Therefore, there is a need in the art for a process that is used to form reliable contact structures and solve the problems described above.

### SUMMARY

Embodiments of the present disclosure generally relate to methods and processes for selectively depositing a metal fill layer into a feature on the surface of a semiconductor structure. More specifically, embodiments described herein provide for methods of super-conformally depositing a metal fill layer into a feature on the surface of a semiconductor structure in a bottom-up manner.

In some embodiments, a method of forming a contact structure includes performing a preclean operation on a contact structure to form a precleaned contact structure. The contact structure includes a silicon-based portion exposed in a cavity of a substrate. The substrate has a bottom surface of the cavity, an interior sidewall of the cavity, and a top surface. The contact structure further includes a liner layer disposed on the interior sidewall of the cavity. The method further includes depositing a metal layer over the precleaned contact structure to form a deposited contact structure. The deposited contact structure has a first layer is deposited on the bottom surface of the cavity, and a second layer is deposited onto the liner layer and the top surface. The method further includes introducing a metal halide precursor to the deposited contact structure to at least partially remove the second layer from the deposited contact structure to form an etched contact structure. The method further includes depositing a metal fill layer onto the first layer to form a filled contact structure. The deposited metal fill layer comprises a super conformal profile.

In some embodiments, a method of forming a contact structure includes performing a preclean operation on a contact structure to form a precleaned contact structure. The contact structure includes a silicon-based portion exposed in a cavity of a substrate. The substrate has a bottom surface of the cavity defined by a lowermost exposed surface of the cavity, an interior sidewall of the cavity, and a top surface. The contact structure further includes a liner layer disposed on the interior sidewall of the cavity, and a volume of the cavity. The volume of the cavity is defined by the silicon based portion exposed in the cavity of the substrate, and the liner layer disposed on the interior sidewall of the cavity. The method further includes depositing a metal layer over the precleaned contact structure to form a deposited contact structure. The deposited contact structure includes a first layer deposited on the bottom surface of the cavity, and a second layer deposited onto the liner layer and the top surface. The method further includes introducing a metal halide precursor to the deposited contact structure to at least partially remove the second layer from the deposited contact structure to form an etched contact structure. The method further includes performing a cyclic processing operation to deposit a selective metal fill layer on the etched contact structure to form a bottom-up metal filled contact structure. The cyclic processing operation comprising a first processing operation and a second processing operation.

In some embodiments, a substrate processing system includes a processing chamber having a first pedestal and a second pedestal. The substrate processing system further includes a controller coupled to the processing chamber. The controller is configured to introduce a metal halide precursor to a substrate to selectively remove a metal layer from the substrate. The substrate includes a first metal layer disposed on a bottom surface of a cavity in the substrate. The bottom surface of the cavity is defined by a lowermost exposed surface of the cavity. The substrate further includes a second metal layer disposed on an interior sidewall of the cavity and a top surface of the substrate. The controller is further configured to conformally deposit a metal gapfill layer into the cavity. The metal gapfill layer includes a first metal layer disposed on the bottom surface of the cavity and a second metal layer disposed on the interior sidewall of the cavity above the first metal layer. The controller is further configured to selectively remove the second metal layer.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flow diagram depicting a method of processing a contact structure, according to an embodiment described herein.

FIG. 2A is a cross-sectional view of a contact structure, according to an embodiment described herein.

FIG. 2B is a cross-sectional view of a contact structure, according to an embodiment described herein.

FIG. 2C is a cross-sectional view of a contact structure, according to an embodiment described herein.

FIG. 2D is a cross-sectional view of a contact structure, according to an embodiment described herein.

FIG. 2E is a cross-sectional view of a contact structure, according to an embodiment described herein.

FIG. 2F is a cross-sectional view of a contact structure, according to an embodiment described herein.

FIG. 3 is a top view of a multi-chamber processing system, according to an embodiment described herein.

FIG. 4A is a cross-sectional view of a processing chamber, according to an embodiment described herein.

FIG. 4B is a cross-sectional view of a processing chamber, according to an embodiment described herein.

FIG. 5 is a profile view of a multiple pedestal processing assembly, according to an embodiment described herein.

FIG. 6 is a top view of a multiple pedestal processing assembly, according to an embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The methods disclosed herein are effective for metal gapfill processes. Generally, multiple metal gapfill materials may be integrated into such processes, but for the sake of brevity, examples discussed use tungsten. The methods disclosed herein are not meant to be limited to only tungsten, but may also be effective in depositing other metal gapfill materials such as molybdenum.

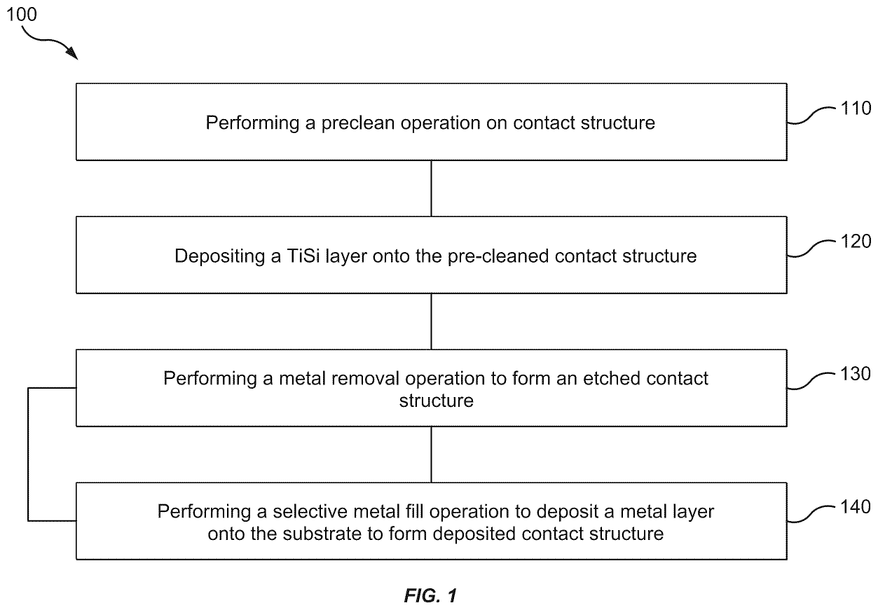

FIG. 1 illustrates a process flow diagram of a method 100 of forming a contact structure on a semiconductor surface. For the purposes of the present disclosure, the terms “substrate” and “contact structure” may be used interchangeably. In the method 100 of FIG. 1, a loop of in-situ MoCl₅ soaking processes and fluorine-free-tungsten (FFW) cap deposition methods are integrated to deposit super-conformal gapfill layers and progressively fill a semiconductor feature (e.g., a cavity) in a controlled, efficient, and cost-effective bottom-up profile. Aspects of the methods disclosed herein may also be conducted in a single processing chamber configured to perform multiple process operations simultaneously.

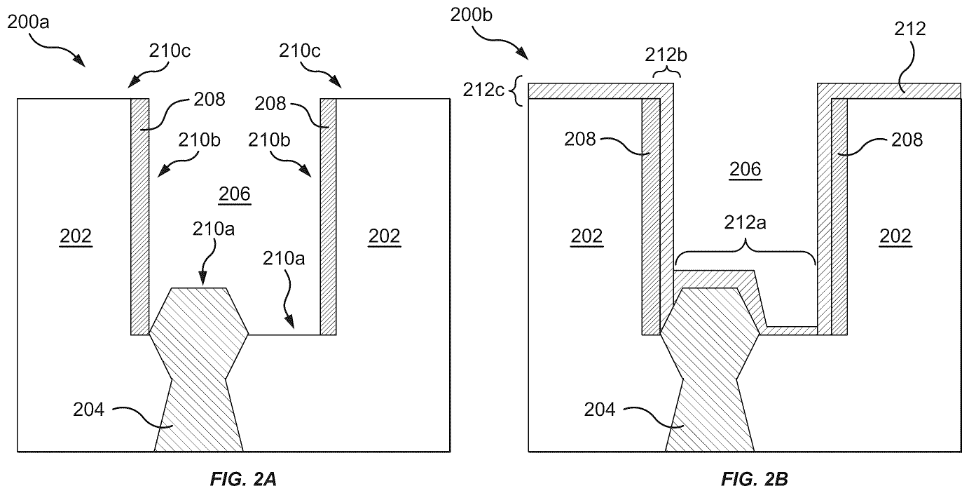

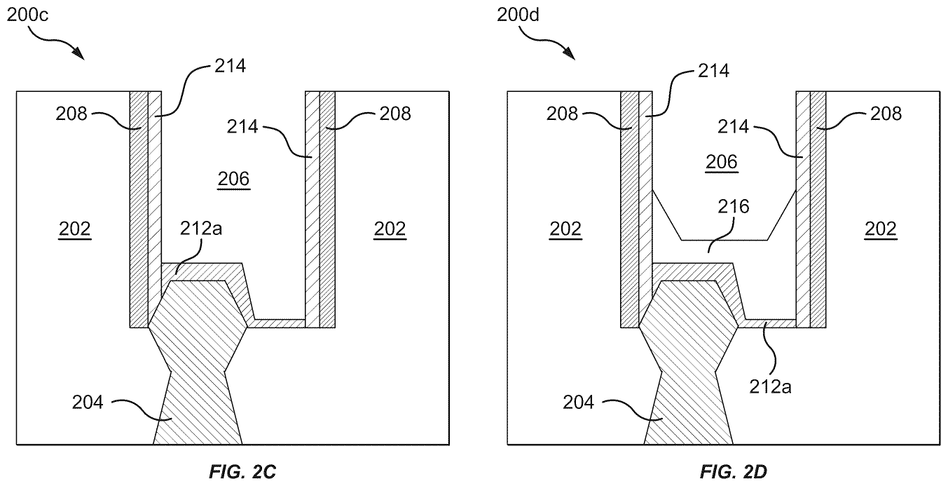

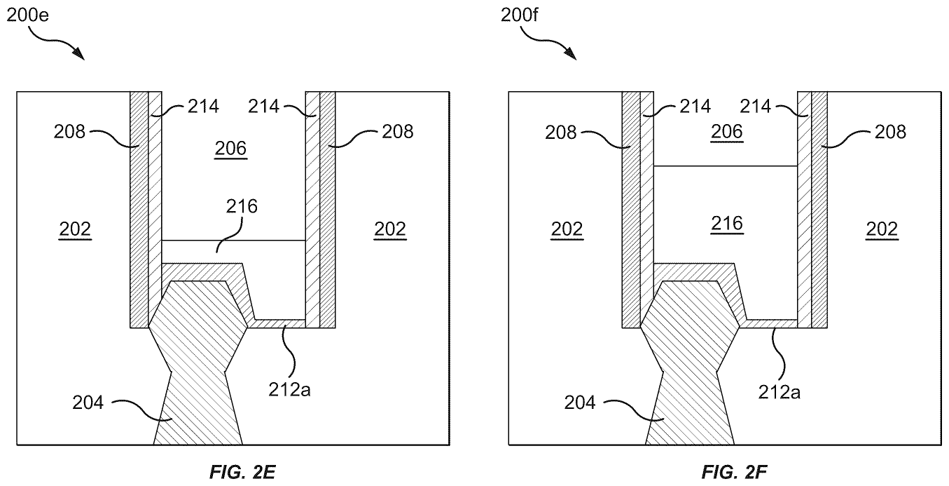

In operation 110 of the method 100, a preclean process is performed to remove any contaminates and/or oxidation from surfaces of a contact structure, such as a contact structure 200a as depicted in FIG. 2A. The contact structure has a silicon-based portion 204 that is exposed in a cavity 206 of a substrate 202 formed of a dielectric material (e.g., silicon dioxide, silicon nitride, etc.). In some embodiments, the silicon-based portion 204 may be a silicon material or a silicon germanium (SiGe) material. The substrate 202 may include a bottom surface 210a of the cavity 206, an interior sidewall 210b of the cavity 206, and a top surface 210c of the substrate 202. In some embodiments, a liner layer 208 is disposed on the interior sidewall 210b of the cavity 206. The liner layer may be composed of silicon nitride (SiN), SiOC, SiONC, or any other Si based dielectric. In at least one embodiment, the liner layer is a bilayer liner, such as SiN/SiO₂ or SiN/SiOC.

In some embodiments, the preclean process includes one or more of etching, reducing, oxidizing, hydroxylating, annealing, and/or thermally treating the contact structure 200a. In at least one embodiment, the preclean process includes a radical-based pre-cleaning technique. The radical-based pre-cleaning technique may include utilizing a remote plasma source to provide a radical containing gas to the contact structure 200a.

In operation 120 of the method 100, the contact structure 200a is subjected to a Ti deposition process to deposit a Ti based layer 212 over the bottom surface 210a of the cavity 206 (e.g., layer 212a), the interior sidewall 210b and/or the liner layer 208 is disposed on the interior sidewall 210b of the cavity 206 (e.g., layer 212b), and the top surface 210c of the substrate 202 (e.g., layer 212c), as illustrated by the contact structure 200b depicted in FIG. 2B. In some embodiments, the Ti deposition process includes a plasma enhanced Ti deposition (PE-Ti) process, such as a plasma enhanced chemical vapor deposition (PE-CVD) process using low selective direct plasma, to deposit a Ti based layer 212 over the contact structure 200b and components thereof. In one or more embodiments, the Ti deposition process includes a high selectivity remote plasma CVD-Ti, plasma enhanced atomic layer deposition (PE-ALD) Ti, or thermal CVD/ALD TiSi process. In at least one embodiment, the Ti deposition process includes the use of a chlorine (Cl) containing precursor.

Generally, the deposited Ti layer 212 includes Ti, TiSi, TiN, or combinations thereof. The Ti based layer 212 may be a conformal Ti based layer wherein a layer 212a composed of TiSi is deposited onto the bottom surface 210a of the cavity 206, and layers 212b and 212c composed of Ti, TiSi, TiN, or a combination thereof are deposited onto the interior sidewall 210b and the top surface 210c of the substrate 202. In some embodiments, layers 212a, 212b, and 212c may each independently include a thickness of about 1,000 nm or less, such as about 500 nm or less, such as about 100 nm or less, such as about 10 nm or less, such as about 3 nm to about 8 nm, such as about 4 nm to about 7 nm, such as about 5 nm to about 6 nm, alternatively about 3 nm to about 4 nm, alternatively about 4 nm to about 5 nm, alternatively about 6 nm to about 7 nm, alternatively about 7 nm to about 8 nm.

In operation 130 of the method 100, the contact structure 200b is subjected to a metal removal operation to partially or fully remove layer(s) 212b and/or 212c, as illustrated by the contact structure 200c depicted in FIG. 2C. The metal removal operation may include removing the targeted Ti based layers via a metal halide soak process. In some embodiments, the metal halide soak process includes introducing metal halide precursor, such as a molybdenum halide containing precursor, a tungsten halide containing precursor, a titanium halide containing precursor, or a combination thereof, to the contact structure 200b to at least partially remove layer(s) 212b and/or 212c. The metal halide precursor may include MoCl₅, WCl₅, TiCl₅, or a combination thereof. In at least one embodiment, the metal removal operation may result in the formation of a residual layer 214. The residual layer 214 may include Ti and/or halide residue from the metal halide soak process.

In operation 140 of the method 100, the contact structure 200c is subjected to a selective metal fill operation (e.g., fluorine-free tungsten (FFW) process) to cover all junction silicide (e.g., layer 212a) and/or fill the cavity 206 with a metal layer (e.g., layer 216), as illustrated by the contact structure 200d depicted in FIG. 2D. The metal layer 216 may be formed by introducing a metal precursor, such as a W precursor, a Mo precursor, or a combination thereof, to the contact structure 200c and performing a deposition process thereon. The selective metal fill operation may include any one or more suitable deposition processes, such as a CVD process, a pulsed CVD process (alternating chemical vapor deposition and purge processes), or an ALD process. In at least one embodiment, the metal precursor includes WCl₅, WCl₆, or a combination thereof. Aspects of the selective metal fill operation may be altered such that the deposited metal fill layer has a super conformal profile (e.g., limited metal layer 216 deposition onto the interior sidewalls 210b of the cavity 206 and substantially no metal layer 216 deposition the top surface 210c of the substrate 202) having a thin metal layer 216 deposited on the layer 212a and the interior sidewalls 210b of the cavity 206.

In some embodiments, operations 130 and 140 may be cyclically performed to achieve a bottom-up metal fill profile, such that the cavity 206 is progressively filled, at a controllable rate, selectivity, and uniformity, with the metal layer 216 via multiple iterations of operations 130 and 140. For instance, the contact structure 200d may be subjected to a metal removal operation 130 to partially or fully remove the metal layer 216 from the interior sidewalls 210b of the cavity 206, as illustrated by the contact structure 200e depicted in FIG. 2E. Subsequently or simultaneously, the contact structure 200e is subjected to additional selective metal fill operation(s) 140 to fill the cavity 206 with a metal layer (e.g., layer 216), as illustrated by the contact structure 200f depicted in FIG. 2F. In some embodiments, operations 130 and 140 may be performed in any suitable number of cycles to achieve a suitable metal layer 216 deposited in the cavity 206. In at least one embodiment, operations 130 and 140 may be cyclically repeated such that the deposited metal layer 216 occupies about 10% or greater of the volume of the cavity, such as about 50% or greater, such as about 90% or greater, such as about 99% or greater, such as about 10% to about 30%. In at least one embodiment, operations 130 and 140 may be cyclically conducted for at least 1 cycle, such as at least 5 cycles, such as at least 10 cycles, such as 2 cycles to 8 cycles, such as 3 cycles to 7 cycles, such as 4 cycles to 6 cycles, alternatively 2 cycles to 3 cycles, alternatively 3 cycles to 4 cycles, alternatively 4 cycles to 5 cycles, alternatively 5 cycles to 6 cycles, alternatively 6 cycles to 7 cycles, alternatively 7 cycles to 8 cycles.

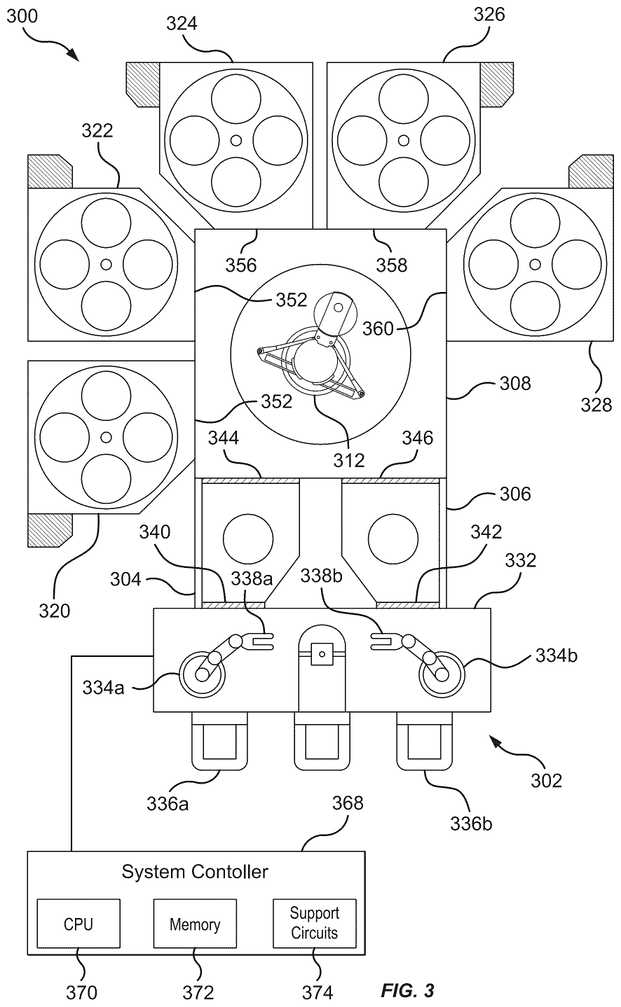

FIG. 3 is a schematic plan view of a multi-chamber substrate processing system 300. The substrate processing system 300 is capable of depositing a seamless fill of a metal fill material from the bottom of a feature, upward to the top of the feature, without breaking vacuum. The substrate processing system 300 generally includes a factory interface 302, load lock chambers 304, 306, a transfer chamber 308, a transfer robot 312, and processing chambers 320, 322, 324, 326, and 328.

Substrates in the substrate processing system 300 can be processed in and transferred between the various chambers without exposing the substrates to an ambient environment that is exterior to the substrate processing system 300. Furthermore, the substrates can be processed in and transferred between the various chambers maintained at a low pressure, or a vacuum environment without breaking the low pressure or vacuum environment. The substrate processing system 300 is capable of maintaining pressures between about 0.01 Torr to about 760 Torr. Accordingly, the substrate processing system 100 may provide for an integrated solution for processing of substrates.

Examples of processing systems that may be suitably modified in accordance with the teachings provided herein include the Endura®, Producer®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In FIG. 3, the factory interface 302 includes a docking station 332 and factory interface robots 334a, 334b to facilitate transfer of substrates. The docking station 332 is configured to accept one or more front opening unified pods (FOUPs) 336a, 336b. In some examples, the factory interface robots 334a, 334b include blades 338a, 338b, respectively. The blades 338a, 338b are configured to transfer the substrates from the factory interface 302 to the load lock chambers 304, 306.

The load lock chambers 304, 306 have ports 340, 342, respectively, coupled to the factory interface 302 and ports 344, 346, respectively, coupled to the transfer chamber 308. The transfer chamber 308 includes ports 352, 354, 356, 358, 360 coupled to processing chambers 320, 322, 324, 326, 328, respectively. The ports 344, 346, 352, 354, 356, 358, 360 can be slit valve openings with slit valves for passing substrates through by the transfer robot 312. The ports 344, 346, 352, 354, 356, 358, 360 are configured to provide seals between respective chambers to prevent gases from passing between the respective chambers.

The load lock chambers 304, 306, the transfer chamber 308, and the processing chambers 320, 322, 324, 326, 328 may be fluidly coupled to a gas and pressure control system (not shown). The gas and pressure control system can include one or more gas pumps (e.g., turbo pumps, cryo-pumps, roughing pumps, etc.), gas sources, various valves, and conduits fluidly coupled to the load lock chambers 304, 306, the transfer chamber 308, and the processing chambers 320, 322, 324, 326, 328. In operation, the factory interface robots 334a, 334b transfer substrates from front opening unified pods (FOUPs) 336a, 336b through the ports 340, 342 to the load lock chambers 304, 306. The gas and pressure control system then pumps down the load lock chambers 304, 306. The gas and pressure control system further maintains the transfer chamber 308 with an interior low pressure or vacuum environment (which may include an inert gas). Hence, the pumping down of the load lock chambers 304, 306 facilitates passing substrates between, for example, the atmospheric environment of the factory interface 302 and the low pressure or vacuum environment of the transfer chamber 308.

With substrates in the load lock chambers 304, 306 that have been pumped down, the transfer robot 312 transfers the substrates from the load lock chambers 304, 306 into the transfer chamber 308 through the ports 344, 346. The transfer robot 312 is then capable of transferring the substrates to and/or between any of the processing chambers 320, 322, 324, 326, 328 through the ports 352, 354, 356, 358, 360, respectively, for processing. The transfer of the substrates within and among the various chambers can be in the low pressure or vacuum environment provided by the gas and pressure control system.

The processing chambers 320, 322, 324, 326, 328 include multiple processing stations disposed within a common processing region. The processing chambers 320, 322, 324, 326, 328 can be any appropriate chamber for processing a substrate. In some examples, the processing chamber 320 can be capable of performing an etch process, the processing chamber 322 can be capable of performing a cleaning process, and the processing chambers 326, 328 can be capable of performing respective growth (e.g., deposition) processes. The processing chamber 320 may be a Selectra™ Etch chamber available from Applied Materials of Santa Clara, California. The processing chamber 322 may be a SiCoNi™ Pre-clean chamber available from Applied Materials of Santa Clara, California. The processing chamber 326, or 328, may be a Volta™ CVD/ALD chamber, or Encore™ PVD chambers available from Applied Materials of Santa Clara, California.

A system controller 368 is coupled to the substrate processing system 300 for controlling the substrate processing system 300 or components thereof. For example, the system controller 368 may control the operation of the substrate processing system 300 using a direct control of the processing chambers 320, 322, 324, 326, 328 of the substrate processing system 300 or by controlling controllers associated with the processing chambers 320, 322, 324, 326, 328. In operation, the system controller 368 enables data collection and feedback from the respective chambers to coordinate performance of the substrate processing system 300.

The system controller 368 generally includes one or more processors such as a central processing unit (CPU) 370, memory 372, and support circuits 374. The CPU 370 may be one of any form of a general-purpose processor that can be used in an industrial setting. In some embodiments, the memory 372 includes one or more non-transitory computer readable media storing executable instructions that, when executed by a processor, (such as the CPU 370) causes the processor to perform operations. The memory 372 is accessible by the CPU 370 and may be one or more of memory such as random access memory (RAM), read only memory (ROM), floppy disk, hard disk, or any other form of digital storage, local or remote. The support circuits 374 are coupled to the CPU 370 and may comprise cache, clock circuits, input/output subsystems, power supplies, and the like. The various methods disclosed herein may generally be implemented under the control of the CPU 370, by the CPU 370 executing computer instruction code stored in the memory 372 (or in memory of a particular processing chamber) as, for example, a software routine. That is, the computer program product is tangibly embodied on the memory 372 (or non-transitory computer-readable medium or machine-readable storage device). When the computer instruction code is executed by the CPU 370, the CPU 370 controls the chambers to perform processes in accordance with the various methods.

The instructions in memory 372 may be in the form of a program product, such as a program that implements the methods of the present disclosure. In one example, the disclosure may be implemented as a program product stored on a computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

In particular embodiments, at least one of the processing chambers 320, 322 is a pre-clean chamber to be utilized in operation 110 of the method 100, and at least one of the processing chambers 324, 326, 328 is a chemical vapor deposition (CVD) chamber to be utilized in operation 120 of the method 100. In operation, a contact structure having a feature formed therein may be transferred to a first processing chamber to be utilized in operation 130 of the method 100 (e.g., one of the processing chambers 322, 324), wherein the feature is subjected to a metal removal process. The substrate may then be transferred to a second processing chamber (e.g., one of the processing chambers 324, 326, 328) to be utilized in operation 140 of the method 100. The substrate may be transferred to a second processing chamber without breaking vacuum where a metal layer, for example, a tungsten layer, is deposited over the feature. The substrate may then be transferred to a third processing chamber without breaking vacuum for additional processing. Other processing systems can be implemented in various embodiments.

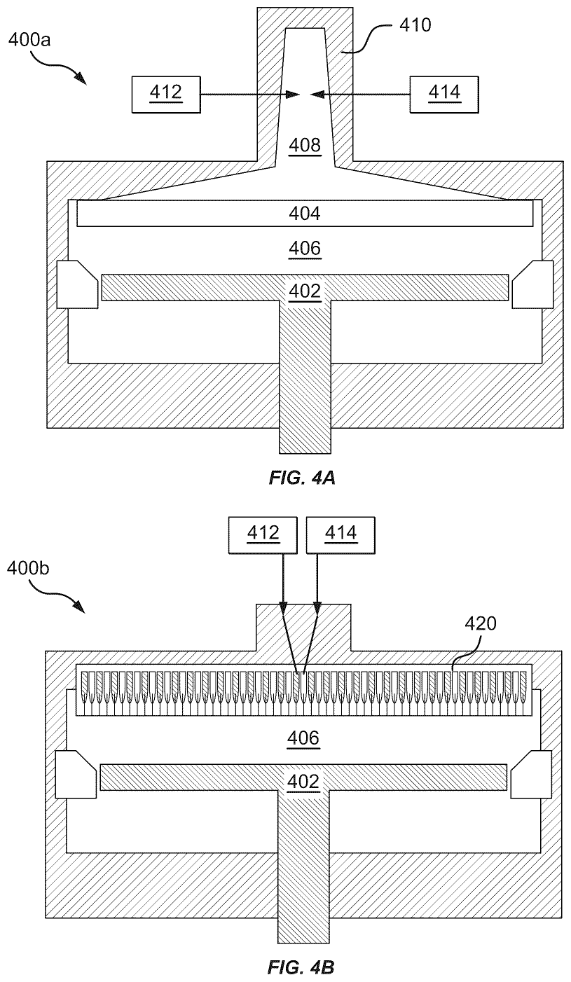

In some embodiments, a processing chamber can include a single pedestal processing chamber, such as the processing chamber 400a of FIG. 4A and/or the processing chamber 400b of FIG. 4B. Either of the processing chambers 400a and/or 400b may be used to perform the method 100 for depositing a metal layer 216 into a cavity 206 of a substrate 202 via a bottom-up super conformal deposition profile, as described above. In some embodiments, operation 130 and operation 140 of the method 100 are performed in the same processing chamber.

The processing chamber 400a of FIG. 4A may be configured such that a process gas 412 of operation 130 and a process gas 414 of operation 140 of the method 100 share the same flow path 408 from a funnel lid configuration 410 to a distribution plate 404. The distribution plate 404 allows the gases to flow uniformly there through into a processing volume 406 and onto a substrate (e.g., substrate 202) disposed on a pedestal 402 therein. The processing chamber 400b of FIG. 4B may be configured such that the process gas 412 of operation 130 and the process gas 414 of operation 140 of the method 100 are flowed into the processing volume 406 using different flow paths. For instance, a dual channel spiral lid configuration 420 may be employed to avoid mixing the process gas 412 of operation 130 and the process gas 414 of operation 140 during the method 100.

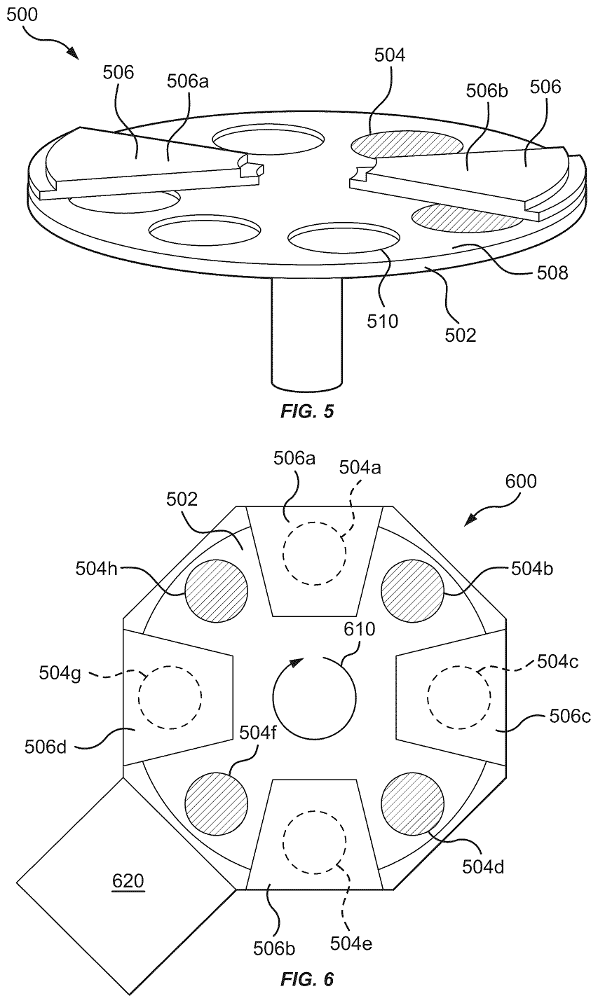

In some embodiments, a processing chamber can include a multiple pedestal processing chamber including a multiple pedestal processing assembly, such as the processing assembly 500 of FIG. 5. In at least one embodiment, the processing assembly 500 can be configured as a carousel-type assembly in which a susceptor assembly 502 includes a plurality of pedestals 504. In other words, the susceptor assembly 502 can hold a plurality of substrates, wherein the substrate is placed in a recess 510 disposed in a top surface 508 of the susceptor assembly 502 above one of the pedestals 504. As shown in FIG. 5, the processing assembly 500 includes a gas distribution assembly 506 which can include a plurality of separate injector units (e.g., 506a and 506b), each injector unit being capable of performing either operation 130 or operation 140 of the method 100 as the wafer is moved beneath the injector unit. The number of injector units is shown for illustrative purposes only. It will be understood that more or less injector units can be included. In some embodiments, there are a sufficient number of injector units to form a shape conforming to the shape of the susceptor assembly 502. In some embodiments, each of the individual injector units may be independently moved, removed and/or replaced without affecting any of the other injector units. For example, one segment may be raised to permit a robot to access the region between the susceptor assembly 502 and gas distribution assembly 506 to load/unload substrates.

In some embodiments, a multiple pedestal processing assembly includes multiple gas injector units that can be used to process multiple substrates simultaneously, such that the substrates experience the same process flow. For example, as shown in FIG. 6, the processing assembly 600 may include one or more gas injector units (e.g., 506a, 506b, 506c, and 506d) and one or more pedestals (e.g., 504a, 504b, 504c, 504d, 504c, 504f, 504g, and 504h). At the outset of processing, at least one of the pedestals 504 can be positioned between individual gas injector units (e.g., 506a, 506b, 506c, and 506d) of the gas distribution assembly 506. Rotating 610 the susceptor assembly 502 will result in progression of the pedestals 504 from a first individual gas injector unit to a second individual gas injector unit, wherein each of the individual gas injector units (e.g., 506a, 506b, 506c, and 506d) are independently configured to perform operation 130 or operation 140 of the method 100. In some embodiments, the processing assembly 600 includes the same number of pedestals 504 and individual gas injector units of the gas distribution assembly 506. In some embodiments, the number of pedestals 504 and individual gas injector units of the gas distribution assembly 506 included in the processing assembly 600 are independent of each other.

The processing assembly 600 shown in FIG. 6 is merely representative of one possible configuration of a multiple pedestal processing assembly, and should not be taken as limiting the scope of the disclosure. Here, the processing assembly 600 includes a plurality of gas injector units. In the embodiment shown, there are four gas injector units (e.g., 506a, 506b, 506c, and 506d) evenly spaced about the processing assembly 600. The processing assembly 600 shown is octagonal. However, those skilled in the art will understand that this is one possible shape and should not be taken as limiting the scope of the disclosure. The gas injector units (e.g., 506a, 506b, 506c, and 506d) of the gas distribution assembly 506 as shown are trapezoidal, but can be any suitable shape to necessary to perform operation 130 and/or operation 140 of the method 100.

The embodiment shown in FIG. 6 includes a load lock chamber 620, or an auxiliary chamber like a buffer station. Such a component is connected to a side of the multiple pedestal processing chamber to allow substrates (e.g., a contact structure 200a) to be loaded/unloaded from the multiple pedestal processing chamber.

Rotation of the susceptor assembly 502 can be continuous or intermittent (discontinuous). In continuous processing, the wafers are constantly rotating so that they are exposed to each of the individual injector units in tum. In discontinuous processing, the pedestals 504 (e.g., a pedestal having a contact structure deposited thereon) can be moved to a first gas injector unit and stopped, and then to a second gas injector unit. In some embodiments, the rotation of the susceptor assembly 502 is paused such that the locations of the pedestals 504 are between individual gas injector units. Such discontinuous processes may provide time for additional processing routines to be performed between the performance of each individual operation of the independently configured gas injector units.

Overall, methods disclosed herein integrate a loop of in-situ metal halide (e.g., MoCl₅) soaking processes and metal fill (e.g., fluorine-free-tungsten (FFW) cap) deposition methods to deposit super-conformal gapfill layers and progressively fill a semiconductor feature (e.g., a cavity) in a controlled, efficient, and cost-effective bottom-up profile. Additionally, aspects of the methods disclosed herein may also be conducted in a single processing chamber configured to perform multiple process operations simultaneously.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or nonvolatile memory. In some embodiments, the computer readable media may include a non-transitory computer readable medium.

While the foregoing is directed to embodiments of the present disclosure, other and further embodiments of the disclosure may be devised without departing from the basic scope thereof, and the scope thereof is determined by the claims that follow.

We claim:

1. A method of forming a contact structure, the method comprising:
performing a preclean operation on a contact structure to form a precleaned contact structure, the contact structure comprising:
a silicon-based portion exposed in a cavity of a substrate, the substrate comprising a bottom surface of the cavity, an interior sidewall of the cavity, and a top surface, and
a liner layer disposed on the interior sidewall of the cavity;
depositing a metal layer over the precleaned contact structure to form a deposited contact structure, wherein:
a first layer is deposited on the bottom surface of the cavity, and
a second layer is deposited onto the liner layer and the top surface;
introducing a metal halide precursor to the deposited contact structure to at least partially remove the second layer from the deposited contact structure to form an etched contact structure; and
depositing a metal fill layer onto the first layer to form a filled contact structure, wherein the deposited metal fill layer comprises a super conformal profile.

2. The method of claim 1, wherein the metal halide precursor is selected from the group consisting of MoCl₅, WCl₅, TiCl₅, and combinations thereof.

3. The method of claim 1, wherein the first layer comprises TiSi and the second layer comprises a combination of Ti, TiSi, and TiN.

4. The method of claim 1, wherein depositing the metal fill layer comprises a fluorine-free tungsten (FFW) process comprising introducing a tungsten precursor to the etched contact structure.

5. The method of claim 4, wherein the tungsten precursor is selected from the group consisting of WCl₅, WCl₆, and combinations thereof.

6. The method of claim 4, wherein the FFW process includes a deposition process selected from the group consisting of chemical vapor deposition (CVD) process, a pulsed CVD process, and an atomic layer deposition (ALD) process.

7. A method of forming a contact structure, the method comprising:
performing a preclean operation on a contact structure to form a precleaned contact structure, the contact structure comprising:
a silicon-based portion exposed in a cavity of a substrate, the substrate comprising a bottom surface of the cavity defined by a lowermost exposed surface of the cavity, an interior sidewall of the cavity, and a top surface,
a liner layer disposed on the interior sidewall of the cavity, and
a volume of the cavity, the volume of the cavity being defined by the silicon based portion exposed in the cavity of the substrate and the liner layer disposed on the interior sidewall of the cavity;
depositing a metal layer over the precleaned contact structure to form a deposited contact structure, wherein:
a first layer is deposited on the bottom surface of the cavity, and
a second layer is deposited onto the liner layer and the top surface;
introducing a metal halide precursor to the deposited contact structure to at least partially remove the second layer from the deposited contact structure to form an etched contact structure; and
performing a cyclic processing operation to deposit a selective metal fill layer on the etched contact structure to form a bottom-up metal filled contact structure, the cyclic processing operation comprising a first processing operation and a second processing operation.

8. The method of claim 7, wherein the first processing operation comprises depositing a metal fill layer into the cavity of the substrate, the deposited metal fill layer comprising a first metal layer disposed on the bottom surface of the cavity and a second metal layer disposed on the liner layer above the first metal layer.

9. The method of claim 7, wherein the second processing operation comprises removing the second metal layer from the deposited metal layer.

10. The method of claim 7, wherein the second processing operation is performed subsequent the first processing operation.

11. The method of claim 7, wherein the first processing operation comprises fluorine-free tungsten (FFW) process, the FFW process comprising introducing a tungsten precursor to the cavity of the substrate.

12. The method of claim 11, wherein the tungsten precursor is selected from the group consisting of WCl₅, WCl₆, and combinations thereof.

13. The method of claim 11, wherein the FFW process includes a deposition process selected from the group consisting of chemical vapor deposition (CVD) process, a pulsed CVD process, and an atomic layer deposition (ALD) process.

14. The method of claim 7, wherein the second processing operation comprises introducing a molybdenum halide compound to the cavity of the substrate.

15. The method of claim 14, wherein the molybdenum halide compound comprises MoCl₅.

16. The method of claim 7, wherein the cyclic processing operation is performed for 2 cycles to 8 cycles.

17. The method of claim 7, wherein the cyclic processing operation is performed for a number of cycles such that the selective metal fill layer occupies about 10% or more of the volume of the cavity.

18. A substrate processing system, comprising:
a processing chamber having a first pedestal and a second pedestal; and
a controller coupled to the processing chamber, configured to:
introduce a metal halide precursor to a substrate to selectively remove a metal layer from the substrate, the substrate comprising:
a first metal layer disposed on a bottom surface of a cavity in the substrate, the bottom surface of the cavity being defined by a lowermost exposed surface of the cavity, and
a second metal layer disposed on an interior sidewall of the cavity and a top surface of the substrate;
conformally deposit a metal gapfill layer into the cavity, the metal gapfill layer comprising a first metal layer disposed on the bottom surface of the cavity and a second metal layer disposed on the interior sidewall of the cavity above the first metal layer; and
selectively remove the second metal layer.

19. The substrate processing system of claim 18, wherein the first pedestal and the second pedestal are positioned on a susceptor assembly within the processing chamber, the susceptor assembly configured to rotate within the processing chamber.

20. The substrate processing system of claim 18, wherein the processing chamber further comprises a gas distribution assembly, the gas distribution assembly comprising a first gas injection unit and a second gas injection unit.
